(19) United States
(12) Patent Application Publication
(10) Pub. No.: US 2020/0141494 A1
(43) Pub. Date: May 7, 2020

(54) SEAL STRUCTURE

(71) Applicant: HONDA MOTOR CO., LTD., Tokyo (JP)

(72) Inventors: Takanori SAKAGUCHI, Wako-shi (JP); Kosuke NISHIYAMA, Wako-shi (JP)

(21) Appl. No.: 16/675,178

(22) Filed: Nov. 5, 2019

(30) Foreign Application Priority Data
Nov. 7, 2018 (JP) 2018209521

(51) Int. Cl. F16J 15/02; H05K 7/20

(52) U.S. Cl. CPC F16J 15/022; H05K 7/20272; H05K 7/20218

(57) ABSTRACT

A seal structure includes a seal member interposed between a first surface and a second surface opposing each other to communicate a first passage opening at the first surface and a second passage opening at the second surface in a sealed condition, at least one of the first surface and the second surface being provided with a drain hole. The seal member includes a first seal portion defining an inner opening corresponding to the first passage and the second passage, a second seal portion surrounding the first seal portion and including an extended portion extending away from the first seal portion, and a connecting portion connecting the first seal portion and the second seal portion to each other, the connecting portion defining an opening communicating with the drain hole.

### TECHNICAL FIELD

The present invention relates to a seal structure, and more particularly, to a seal structure using a seal member provided with a drain hole.

### BACKGROUND ART

When a reliable sealing performance is required, a seal may be doubly provided. For instance, when a pair of passages formed in two members are to be communicated with each other via a pair opposing surfaces, a pair of O-rings may be interposed between the opposing surfaces so as to surround the passage concentrically to each other. However, according to this arrangement, the fluid to be sealed may seep into the annular space defined between the two O-rings over time, and the fluid trapped between the two O-rings may impair the durability of the O-rings by thermally expanding when subjected to cyclic heating.

WO2015/055985A1 discloses such a double seal structure. According to this prior art, a pressurized gas consisting of inert gas is fed into the annular space between the two O-rings to “inflate” the sealing system. If the inner O-ring should fail, the pressurized gas prevents the fluid which may be reactive from being discharged to the atmosphere. The pressure of the pressurized gas is monitored for the purpose of detecting a failure in the sealing system. This sealing system is highly effective in preventing leakage of fluid, but is highly complex and expensive to implement owing to the need for a system for feeding and recycling the pressurized gas.

### SUMMARY OF THE INVENTION

In view of such a problem of the prior art, a primary object of the present invention is to provide a sealing structure which is reliable in operation and simple in structure.

To achieve such an object, an embodiment of the present invention provides a seal structure comprising a seal member (50) interposed between a first surface (16) and a second surface (18) opposing each other to communicate a first passage (20) opening at the first surface and a second passage (24) opening at the second surface in a sealed condition, at least one of the first surface and the second surface being provided with a drain hole (26), wherein the seal member (50) includes a first seal portion (54) defining an inner opening (52) corresponding to the first passage (20) and the second passage (24), a second seal portion (56) surrounding the first seal portion (54) and including an extended portion (60) extending away from the first seal portion, and a connecting portion (58) connecting the first seal portion and the second seal portion to each other, the connecting portion defining an opening (62) communicating with the drain hole. Preferably, the opening (62) communicating with the drain hole (26) is defined in a part of the connecting portion extending between the first seal portion (54) and the extended portion (60) of the second seal portion (56).

Thereby, if the first seal portion should fail, the fluid which has leaked through the first seal portion can be expelled from the drain hole in a reliable manner.

Preferably, the first seal portion is circular in shape, and the second seal portion includes a semicircular section (56B) concentrically surrounding the first seal portion, the extended portion (60) being partly defined by a pair of tangential lines extending from the semicircular section.

Thereby, a maximum area can be ensured for the part of the connecting portion located between the first seal portion and the extended portion of the second seal portion where the opening communicating with the drain hole is defined, so that the space defined between the first seal portion and the second seal portion can be communicated with the drain hole in a reliable manner with a minimum amount of material for the seal member.

Preferably, the first seal portion and the second seal portion each have a substantially circular cross section, and the connecting portion comprises a sheet portion extending substantially over an entire area defined between the first seal portion and the second seal portion excluding a localized area surrounding the drain hole. Typically, the seal member is formed by a one-piece molded elastomeric member.

Thereby, the seal member can be manufactured at a low cost, and the handling of the seal member is facilitated.

Preferably, at least one of the first surface and the second surface of the seal member is formed with a recess (28) substantially conformal to the seal member in plan view.

Thus, the positioning of the seal member during the assembly process is facilitated. Also, the degree of compression for the seal member can be accurately controlled.

Preferably, the second seal portion (56) includes a protrusion (59) extending radially outward from a vertically middle portion of an outer periphery of the second seal portion, and having a smaller vertical thickness than the second seal portion. Thereby, the seal member is prevented from sticking out of the recess so that a peripheral part of the seal member is prevented from being inadvertently clamped between the first member and the second member.

The present invention thus provides a sealing structure which is reliable in operation and simple in structure.

### BRIEF DESCRIPTION OF THE DRAWINGS

FIG. 1 is a fragmentary longitudinal sectional view showing a seal structure according to an embodiment of the present invention;

FIG. 2 is an end view of the seal structure as seen in a direction indicated by arrows A in FIG. 1;

FIG. 3 is a view similar to FIG. 2 with a seal member removed;

FIG. 4 is a plan view of the seal member; and

FIG. 5 is a sectional view taken along line V-V in FIG. 4.

### DESCRIPTION OF THE PREFERRED EMBODIMENT(S)

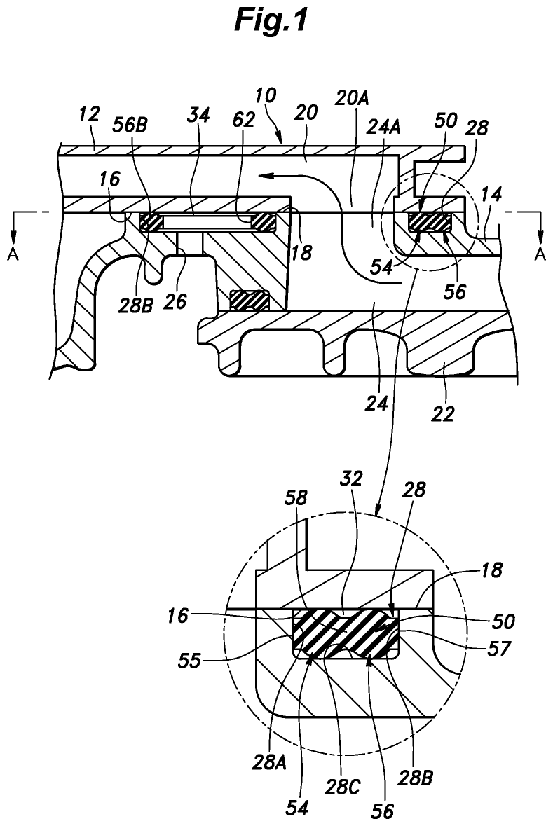

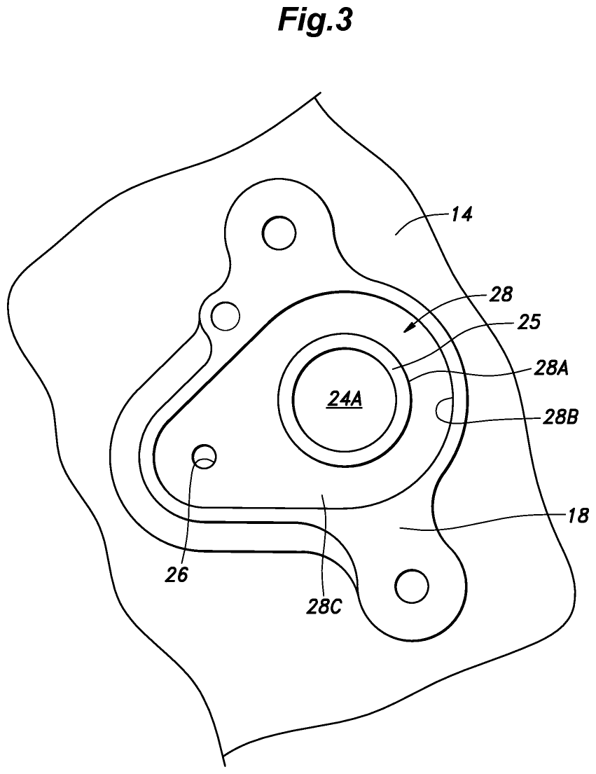

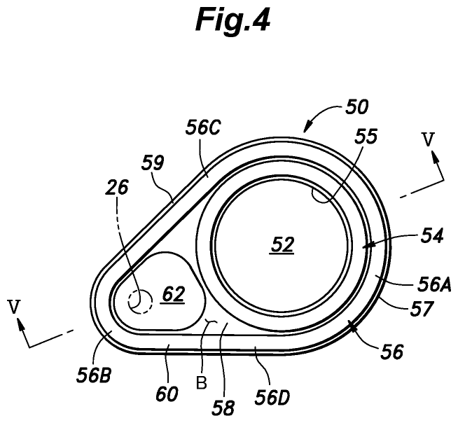

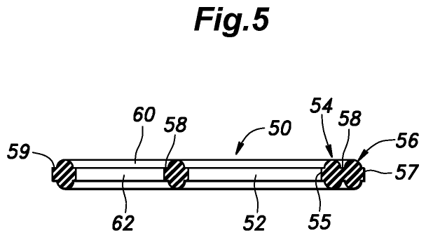

A preferred embodiment of the present invention is described in the following with reference to FIGS. 1 to 5.

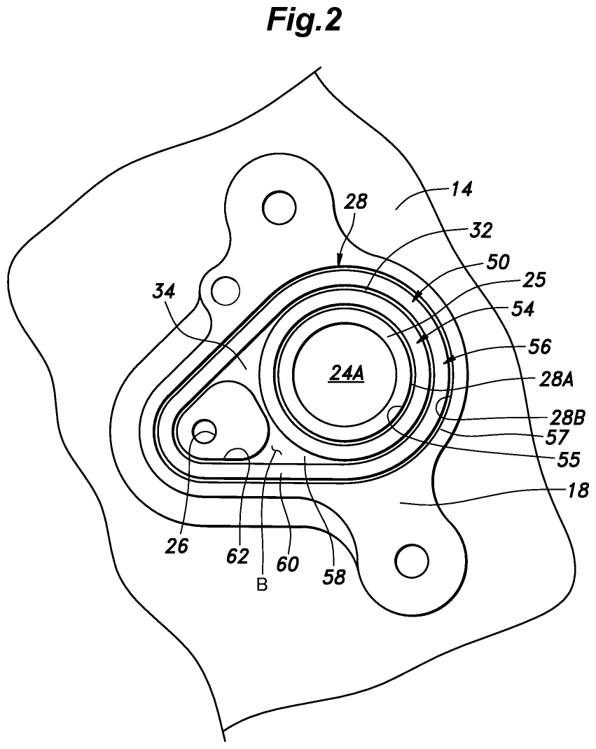

FIGS. 1 and 2 show a seal structure according to an embodiment of the present invention as applied to a liquid-cooled casing 10 for electric power equipment or the like.

The casing 10 includes a first member 12 and a second member 14 that are connected to each other by fasteners not shown in the drawings. A circuit board and other components (not shown in the drawings) are received in the internal space of the casing 10.

The first member 12 has a flat first surface 16 (a lower surface as viewed in FIG. 1). The second member 14 has a flat second surface 18 (an upper surface as viewed in FIG. 1) that opposes the first surface 16.

The first member 12 is provided with an upper coolant passage 20 having an open end 20A at the first surface 16. The second member 14 is provided with a lower coolant passage 24 defined in cooperation with a lower lid member 22 attached to the second member 14. The lower coolant passage 24 has an open end 24A at the second surface 18 so as to communicate with the upper coolant passage 20. The open end 20A of the upper coolant passage 20 and the open end 24A of the lower coolant passage 24 are circular holes having substantially the same inner diameter, and are coaxially aligned with each other. The coolant flows from the lower coolant passage 24 to the upper coolant passage 20 via these open ends 24A and 20A.

The second surface 18 is provided with a recess 28 for receiving a seal member 50. A circular annular boss 25 surrounds the open end 24A of the lower coolant passage 24. The part of the second surface 18 surrounding the recess 28 is flush with the end surface of the annular boss 25. Thus, the recess 28 is provided with an inner peripheral surface 28A defined by the outer circumferential surface of the annular boss 25, and an outer peripheral surface 28B defined by the part of the second member 14 surrounding the recess 28.

The second member 14 is formed with a drain hole 26 located in a part of the recess remote from the annular boss 25 and communicating with the atmosphere.

A seal member 50 is interposed between the first surface 16 and the second surface 18, and in particular is received in the recess 28 formed in the second surface 18 for the purpose of communicating the upper coolant passage 20 opening at the first surface 16 and the lower coolant passage 24 opening at the second surface 18 with each other in a sealed condition.

The seal member 50 is a single piece member formed by molding elastomeric material. For instance, the seal member 50 may be made of vulcanized or urethane rubber. The seal member 50 includes a first seal portion 54 having a circular annular shape and closely surrounding the annular boss 25 in the recess 28. The first seal portion 54 thus has a circular inner opening 52 coaxially aligned with the open end 20A of the upper coolant passage 20 and the open end 24A of the lower coolant passage 24. The seal member 50 further includes a second seal portion 56 having an annular pear shape and surrounding the first seal portion 54, and a connecting portion 58 extending between the first seal portion 54 and the second seal portion 56 and connecting the first seal portion 54 and the second seal portion 56 to each other.

The connecting portion 58 consists of sheet material or membrane. The first seal portion 54 and the second seal portion 56 each consist of a ring having a substantially circular cross section so as to have a portion having a semi-circular cross section protruding upward and downward from the connecting portion 58. The first seal portion 54 and the second seal portion 56 may be considered as protrusions protruding from the upper surface and the lower surface of the connecting portion 58. Alternatively, first seal portion 54 and the second seal portion 56 may be considered as O-rings which are connected to each other by the connecting portion 58. The parts of the first seal portion 54 and the second seal portion 56 protruding from the upper surface and the lower surface may also be provided with rectangular, trapezoidal or other polygonal shapes.

In the illustrated embodiment, the second seal portion 56 includes a first semicircular section 56A that extends concentrically with the first seal portion 54 on one side in the radial direction of the first seal portion 54 in plan view (over an angular range which is slightly greater than 180 degrees), a second semicircular section 56B having a center at a position away from the other radial side of the first seal portion 54 (on the other side opposite to the one side) in plan view (over an angular range which is slightly smaller than 180 degrees), and a pair of linear sections 56C and 56D extending tangentially to the first semicircular section 56A and the second semicircular section 56B so that a pear shaped closed loop is defined by second seal portion 56.

The second semicircular section 56B has a substantially smaller radius than the first semicircular section 56A, and concentrically surrounds the drain hole 26 when placed in the recess 28.

Thus, the second seal portion 56 includes a substantially triangular extended portion 60 (or a lobe) formed by the second semicircular section 56B and the two linear sections 56C and 56D such that the extended portion 60 extends away from the first seal portion 54 in a radially outward direction.

Thus, a substantially triangular space B is defined between the first seal portion 54 and the second seal portion 56 in plan view.

The second seal portion 56 includes the first semicircular section 56A and the second semicircular section 56B, and the circumferential length of the second seal portion 56 is minimized by connecting the first semicircular section 56A and the second semicircular section 56B with each other by the tangential linear sections 56C and 56D.

Thus, the triangular space B is created by minimizing the circumferential length of the second seal portion 56 so that the material cost can be minimized.

The connecting portion 58 includes an arcuate strip part that extends between the first seal portion 54 and the first semicircular section 56A of the second seal portion 56, and a triangular part that extends between the substantially triangular extended portion 60 of the second seal portion 56 and the opposing part of the first seal portion 54. The triangular part of the connecting portion 58 is formed with an opening 62 that surrounds and exposes the drain hole 26. Thus, the opening 62 formed triangular part of the connecting portion 58 communicates with the drain hole 26.

Details of the recess 28 are described in the following with reference to FIGS. 1 to 3. The inner peripheral surface 55 of the first seal portion 54 is in contact with the inner peripheral surface 28A of the recess 28 defined by the outer circumferential surface of the annular boss 25. The outer peripheral surface 57 of the second seal portion 56 is in contact with the outer peripheral surface 28B of the recess 28. The recess 28 has a generally flat bottom surface 28C extending between the inner peripheral surface 55 and the outer peripheral surface 28B of the recess 28. Thus, the inner peripheral surface 28A of the recess 28 is conformal to the inner profile of the first seal portion 54, and the outer peripheral surface 28B of the recess 28 is conformal to the outer profile of the second seal portion 56.

Thus, the seal member 50 can be snugly received by the recess 28, and has an initial height which is somewhat greater than the depth of the recess 28. The second seal portion 56 is provided with an outer protrusion 59 that protrudes radially outward from the outer peripheral surface 57 of the second seal portion 56 and has a same thickness as the connecting portion 58, or a smaller vertical thickness than the second seal portion 56.

Also, the protrusion 59 protrudes from a vertically middle part of the outer peripheral surface 57 of the second seal portion 56. Therefore, when the seal member 50 is placed in the recess 28, the outer protrusion 59 abuts against the outer peripheral surface 28B of the recess 28, and properly positions the seal member 50 in the recess 28 without the risk of allowing any part of the seal member 50 sticking out of the recess 28.

The connecting portion 58 is provided with the opening 62 that allows the space defined between the first seal portion 54 and the second seal portion 56 to communicate with the drain hole 26.

As shown in FIG. 1, the first member 12 is joined to the second member 14 by bolts or the like (not shown in the drawings) so that the seal member 50 is interposed between the first surface 16 of the first member 12 and the bottom surface 28C of the recess 28 formed in the second member 14. The first seal portion 54 and the second seal portion 56 are elastically compressed. As a result, the first seal portion 54 and the second seal portion 56 are in contact with the first surface 16 of the first member 12 and the bottom surface 28C of the recess 28 under compression so that a fluid tight sealing is ensured the junction between the upper coolant passage 20 and the lower coolant passage 24.

Thus, the first surface 16 and the second surface 18 that oppose each other are not required to be in surface contact with other as long as the first member 12 and the second member 14 joined to each other such that the seal member 50 is placed under constant compression.

The connecting portion 58 includes a semicircular narrow strip formed between the first seal portion 54 and the first semicircular section 56A of the second seal portion 56, and a triangular portion formed between the first seal portion 54 and the extended portion 60 of the second seal portion 56. Since the connecting portion 58 has a smaller vertical dimension than the first seal portion 54 and the second seal portion 56 and is connected to vertically middle points of the first seal portion 54 and the second seal portion 56, the spaces defined on either side of the connecting portion 58 in cooperation with the first surface 16 of the first member 12 and the bottom surface 28C of the recess 28 are in communication with the drain hole 26 either directly or via the opening 62 in the connecting portion 58. Therefore, the spaces are kept under the pressure prevailing in the drain hole 26 which may be the atmospheric pressure at all times.

Thus, even when the first seal portion 54 should fail, the fluid that has leaked from the first seal portion 54 is received in the space defined between the first seal portion 54 and the second seal portion 56, and is expelled from the drain hole 26. Therefore, the leaked fluid is prevented from leaking to the outside owing to the presence of the second seal portion 56.

Since a relatively large space is defined between the extended portion 60 and the first seal portion 54, as compared to the narrow space defined between the first semicircular section 56A of the second seal portion 56 and the first seal portion 54, a relatively large area can be ensured to the opening 62 in the connecting portion 58 so that the space defined between the first seal portion 54 and the second seal portion 56 can communicate with the drain hole 26 in a reliable manner even when the seal member 50 is compressed between the first member 12 and the second member 14.

Since the part of the connecting portion 58 located between the first semicircular section 56A of the second seal portion 56 and the first seal portion 54 is narrow in width, a maximum area can be assigned to the part of the connecting portion 58 located between the extended portion 60 of the second seal portion 56 and the first seal portion 54 for the given amount of material for the seal member 50

The present invention has been described in terms of a specific embodiment, but is not limited by such an embodiment, but can be modified in various ways without departing from the spirit of the present invention. For instance, the drain hole 26 may also open at the second surface 18. Also, the recess 28 may be formed in the first member 12. The drain hole 26 may be communicated with the atmosphere, but may also be communicated with a suitable leakage recovery system.

1. A seal structure comprising a seal member interposed between a first surface and a second surface opposing each other to communicate a first passage opening at the first surface and a second passage opening at the second surface in a sealed condition, at least one of the first surface and the second surface being provided with a drain hole,
wherein the seal member includes a first seal portion defining an inner opening corresponding to the first passage and the second passage, a second seal portion surrounding the first seal portion and including an extended portion extending away from the first seal portion, and a connecting portion connecting the first seal portion and the second seal portion to each other, the connecting portion defining an opening communicating with the drain hole.

2. The seal structure according to claim 1, wherein the first seal portion is circular in shape, and the second seal portion includes a semicircular section concentrically surrounding the first seal portion, the extended portion being partly defined by a pair of tangential lines extending from the semicircular section.

3. The seal structure according to claim 1, wherein at least one of the first surface and the second surface of the seal member is formed with a recess substantially conformal to the seal member in plan view.

4. The seal structure according to claim 1, wherein the opening communicating with the drain hole is defined in a part of the connecting portion extending between the first seal portion and the extended portion of the second seal portion.
